(19) United States
(12) Patent Application Publication
(10) Pub. No.: US 2012/0261782 A1
(43) Pub. Date: Oct. 18, 2012

(54) SOLID-STATE IMAGE PICKUP DEVICE AND METHOD OF PRODUCING THE SAME

(75) Inventors: Masahiro Kobayashi, Tokyo (JP); Masatsugu Itahashi, Yokohama-shi (JP); Tetsuya Fudaba, Ebina-shi (JP); Hideo Kobayashi, Tokyo (JP)

(73) Assignee: CANON KABUSHIKI KAISHA, Tokyo (JP)

(21) Appl. No.: 13/517,000

(22) PCT Filed: Dec. 20, 2010
(86) PCT No.: PCT/JP2010/007372

§ 371 Date: Jun. 18, 2012

(30) Foreign Application Priority Data
Dec. 22, 2009 (JP) 2009-291023

(51) Int. Cl. H01L 27/146; H01L 31/0232; H01L 31/18

(52) U.S. Cl. 257/432; 438/70; 257/E27.13; 257/E31.127

(57) ABSTRACT

The present invention provides a solid-state image pickup device that includes a plurality of photoelectric conversion units disposed in a semiconductor substrate, a first planarizing layer disposed at a first principal surface side of the semiconductor substrate where light enters, a color filter layer disposed on the first planarizing layer and including color filters each of which is provided for a corresponding photoelectric conversion unit, and a second planarizing layer disposed on the color filter layer for reducing a level difference between the color filters. In the solid-state image pickup device, a gap is disposed in a position corresponding to a boundary between the neighboring color filters in the color filter layer, the gap extending to the second planarizing layer, and a sealing layer for sealing the gap is disposed on the gap and the second planarizing layer.

### TECHNICAL FIELD

The present invention relates to a solid-state image pickup device, and more specifically, relates to a solid-state image pickup device having gaps between color filters.

### BACKGROUND ART

Patent Literature 1 discloses a structure in which gaps that are filled with a gas are provided between a plurality of color filters in charge-coupled device (CCD)-type and metal-oxide semiconductor (MOS)-type solid-state image pickup devices. In addition, a planarizing layer composed of an acrylic resin is formed on the color filters and the gaps.

Patent Literature 2 discloses a so-called back-illuminated solid-state image pickup device. This solid-state image pickup device has a structure in which transistors are disposed in a first principal surface and a plurality of wiring layers are disposed at a first principal surface side. The structure is illuminated from a second principal surface opposite to the first principal surface. More particularly, color filter components of a color filter are defined as core portions, and cavity portions, which are formed by self-alignment of the neighboring color filter components, are defined as cladding portions. A cavity sealing film for sealing the cavity portions is formed on the color filter. According to Patent Literature 2, the cavity sealing film can suppress failures caused by the penetration of organic films into the cavity portions in cases where micro lenses and the like are provided.

### CITATION LIST

### Patent Literature

PTL 1: Japanese Patent Laid-Open No. 2006-295125

PTL 2: Japanese Patent Laid-Open No. 2009-088415

### SUMMARY OF INVENTION

### Technical Problem

According to the structure disclosed in Patent Literature 1, penetration of a micro lens material into the gaps cannot be sufficiently suppressed when the micro lenses and the like are disposed on a color filter layer. If a considerable amount of the micro lens material enters the gaps, the gaps may be completely filled with the micro lens materials.

According to the structure disclosed in Patent Literature 2, the micro lenses are disposed using a sealing layer. However, in this structure, a level difference between the color filter components having different colors cannot be sufficiently reduced in some cases. If a certain or larger degree of level difference is left, it is difficult to form the micro lenses in a desired shape when the micro lenses are formed on the color filter.

In light of the above-described situation, the present invention provides a technique for maintaining the flatness of a surface of a color filter after the color filter layer is formed and for suppressing a situation where gaps between color filters are almost entirely filled with materials provided on the gaps even if the gaps are provided between the color filters.

### Solution to Problem

In light of the above-described situation, the present invention provides a solid-state image pickup device that includes a plurality of photoelectric conversion units that are disposed in a semiconductor substrate, a first planarizing layer that is disposed at a first principal surface side of the semiconductor substrate where light enters, a color filter layer that is disposed on the first planarizing layer and includes color filters each of which is provided for a corresponding photoelectric conversion unit, and a second planarizing layer that is disposed on the color filter layer and reduces a level difference between the color filters. In the solid-state image pickup device, a gap is disposed in a position corresponding to a boundary between the neighboring color filters in the color filter layer, the gap extending to the second planarizing layer, and a sealing layer for sealing the gap is disposed on the gap and the second planarizing layer.

### Advantageous Effects of Invention

The present invention provides a technique for maintaining the flatness of a surface of a color filter after the color filter layer is formed and for suppressing a situation where gaps between color filters are almost entirely filled with materials provided on the gaps even if the gaps are provided between the color filters.

### BRIEF DESCRIPTION OF DRAWINGS

FIG. 1A is a sectional schematic diagram of a solid-state image pickup device of a first embodiment.

FIG. 1B is a top schematic diagram of the solid-state image pickup device of the first embodiment.

FIG. 2A is a process chart illustrating a process in a production process flow of the solid-state image pickup device of the first embodiment.

FIG. 2B is a process chart illustrating a process in the production process flow of the solid-state image pickup device of the first embodiment.

FIG. 2C is a process chart illustrating a process in the production process flow of the solid-state image pickup device of the first embodiment.

FIG. 2D is a process chart illustrating a process in the production process flow of the solid-state image pickup device of the first embodiment.

FIG. 2E is a process chart illustrating a process in the production process flow of the solid-state image pickup device of the first embodiment.

FIG. 2F is a process chart illustrating a process in the production process flow of the solid-state image pickup device of the first embodiment.

FIG. 2G is a process chart illustrating a process in the production process flow of the solid-state image pickup device of the first embodiment.

FIG. 3 is a sectional schematic diagram of a solid-state image pickup device of a second embodiment.

FIG. 4 is a sectional schematic diagram of a solid-state image pickup device of a third embodiment.

FIG. 5 is a sectional schematic diagram of a solid-state image pickup device of a fourth embodiment.

FIG. 6A is a sectional schematic diagram of a solid-state image pickup device of a fifth embodiment.

FIG. 6B is an explanatory diagram of the solid-state image pickup device for describing an advantage of the fifth embodiment.

FIG. 6C illustrates a comparative example for the fifth embodiment.

FIG. 7A is a sectional schematic diagram of a solid-state image pickup device of a sixth embodiment.

FIG. 7B is an explanatory diagram of the solid-state image pickup device for describing an advantage of the sixth embodiment.

FIG. 7C illustrates a comparative example for the sixth embodiment.

FIG. 8A is a process chart illustrating a process in a production process flow of a solid-state image pickup device of a seventh embodiment.

FIG. 8B is a process chart illustrating a process in the production process flow of the solid-state image pickup device of the seventh embodiment.

FIG. 8C is a process chart illustrating a process in the production process flow of the solid-state image pickup device of the seventh embodiment.

FIG. 8D is a process chart illustrating a process in the production process flow of the solid-state image pickup device of the seventh embodiment.

FIG. 8E is a process chart illustrating a process in the production process flow of the solid-state image pickup device of the seventh embodiment.

FIG. 8F is a process chart illustrating a process in the production process flow of the solid-state image pickup device of the seventh embodiment.

FIG. 8G is a process chart illustrating a process in the production process flow of the solid-state image pickup device of the seventh embodiment.

### DESCRIPTION OF EMBODIMENTS

### First Embodiment

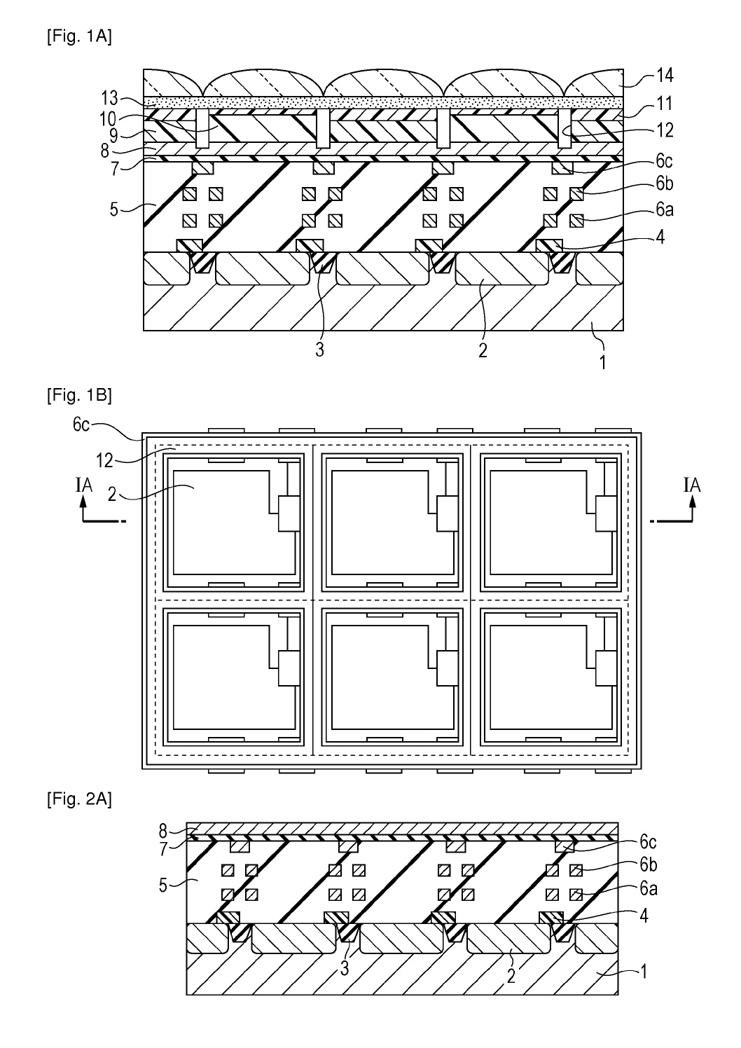

FIG. 1A illustrates a sectional schematic diagram of a solid-state image pickup device of a first embodiment taken along line IA-IA in FIG. 1B. FIG. 1B is a top view illustrating the solid-state image pickup device in FIG. 1A.

Reference numeral 1 denotes a first semiconductor area, which serves as a common area for a plurality of photoelectric conversion units.

Reference numeral 2 denotes second semiconductor areas. Each second semi-conductor area 2 has a conductivity type opposite to that of the first semiconductor area 1, and forms a PN junction together with the first semiconductor area 1. The second semiconductor areas 2 are areas where carriers having the same polarity as signal charges constitute majority carriers. Each photoelectric conversion unit includes a portion of the first semiconductor area and the second semiconductor area.

Reference numeral 3 denotes element isolation portions. The element isolation portions 3 are disposed between neighboring second semiconductor areas 2 and electrically separate the second semiconductor areas 2 from each other. A separation method used here can be an insulating film separation method such as a local oxidation of silicon (LOCOS) isolation method or a shallow trench isolation (STI) method, or a PN junction separation (diffusive separation) method that utilizes a semiconductor area having a conductivity type opposite to that of the second semiconductor areas 2.

Reference numeral 4 denotes pieces of polysilicon, which constitute gates of transistors that are included in pixels. More specifically, the pieces of polysilicon 4 constitute the gates of transfer transistors that transfer the electric charges in the second semiconductor areas 2.

Reference numeral 5 denotes an interlayer insulation film. The interlayer insulation film 5 is used to electrically separate the pieces of polysilicon 4 from wiring layers, or electrically separate different wiring layers from each other. The interlayer insulation film 5 can be formed of, for example, a silicon oxide film.

Reference numerals 6a to 6c denote wiring layers. Here, three wiring layers are provided. Al, Cu, and so forth may be used as main components of materials used to form the wiring layers. The wiring layer 6c, which is disposed at a position farthest from a semiconductor substrate, is referred to as a top wiring layer. It is noted that the number of the wiring layers is not necessarily three.

Reference numeral 7 denotes a protective layer. The protective layer 7 is provided so as to be in contact with the top wiring layer 6c and the interlayer insulation film 5. In addition, an antireflection coating film may be provided in an interface between the protective layer 7 and the interlayer insulation film 5. The protective layer 7 can be formed of, for example, a silicon-nitride film. The antireflection coating film can be formed of a silicon oxynitride film when the interlayer insulation film 5 is formed of a silicon oxide film and the protective layer 7 is formed of a silicon-nitride film.

Reference numerals 8 and 11 respectively denote first and second planarizing layers. The first planarizing layer 8 can function, for example, as an underlying film of a color filter layer. The second planarizing layer 11 can function, for example, as an underlying film of micro lenses.

Reference numerals 9 and 10 respectively denote first and second color filters 9 and 10. The first and second color filters 9 and 10 are disposed between the first planarizing layer 8 and the second planarizing layer 11. The color of the first color filters 9 and the color of the second color filters 10 are different from each other. For example, the color of the first color filters 9 is green and the color of the second color filters 10 is red. The first color filters 9 and the second color filters 10 have film thicknesses different from each other. A level difference caused by the difference in thickness is reduced by the second planarizing layer 11. In addition, blue color filters, which are not shown, can be provided to form a Bayer pattern. The color filter layer includes these color filters of different colors.

Reference numeral 12 denotes gaps. The gaps 12 extend from the second planarizing layer 11 to an intermediate level in the first planarizing layer 8 by penetrating through the color filter layer including the first color filters 9 and the second color filters 10. The gaps 12 are filled with air, or set to a vacuum state. The gaps 12 are disposed at least between the color filters having different colors from each other, extending to the second planarizing layer 11. Incident light is refracted by an interface between each gap 12 and a structure including the second planarizing layer 11, the color filter layer, and the first planarizing layer 8. The refracted light is directed to each photoelectric conversion unit.

Reference numeral 13 denotes a sealing layer. The sealing layer 13 is disposed at least on the gaps 12 so as to seal the gaps 12. The sealing layer 13 can be disposed on the second planarizing layer 11 and the gaps 12. The sealing layer 13 can be formed of a material having a relatively high viscosity to prevent the sealing layer 13 from completely filling the gaps 12.

Reference numeral 14 denotes micro lenses. Each micro lens 14 is provided for a corresponding photoelectric conversion unit.

FIG. 1B illustrates a top view of the solid-state image pickup device of this embodiment. To facilitate understanding of features of the present invention here, FIG. 1B only illustrates the gaps 12, the wiring layer 6c which is the top wiring layer in the pixel area, the second semiconductor areas 2 and the element isolation portions 3. Other components are omitted from FIG. 1B. As clearly illustrated in FIG. 1B, patterns of the wiring layer 6c and the gaps 12 are superposed with each other when seen from above. In other words, the gaps 12 and the wiring layer 6c are arranged so as to be partly superposed with each other when the gaps 12 are vertically projected onto the wiring layer 6c. This structure can suppress damage to the photoelectric conversion units and the semiconductor substrate that includes the photoelectric conversion units formed therein during an etching process in which the gaps 12 are formed. The vertical projection of the gaps 12 can be completely included in the wiring layer 6c as illustrated in FIG. 1B.

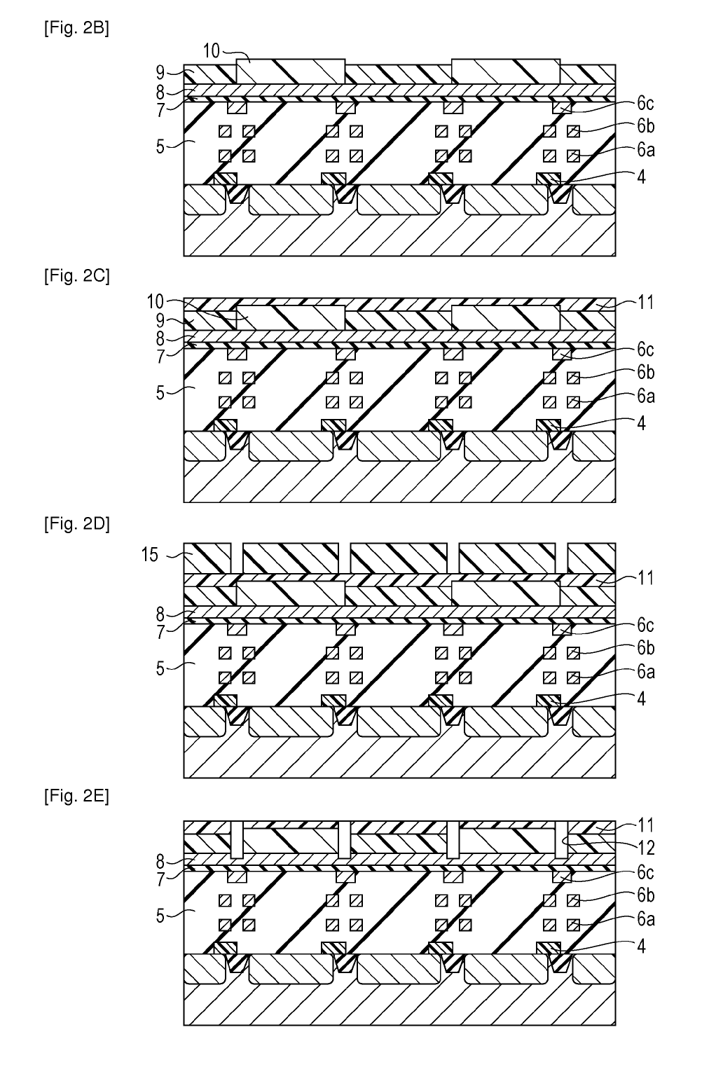

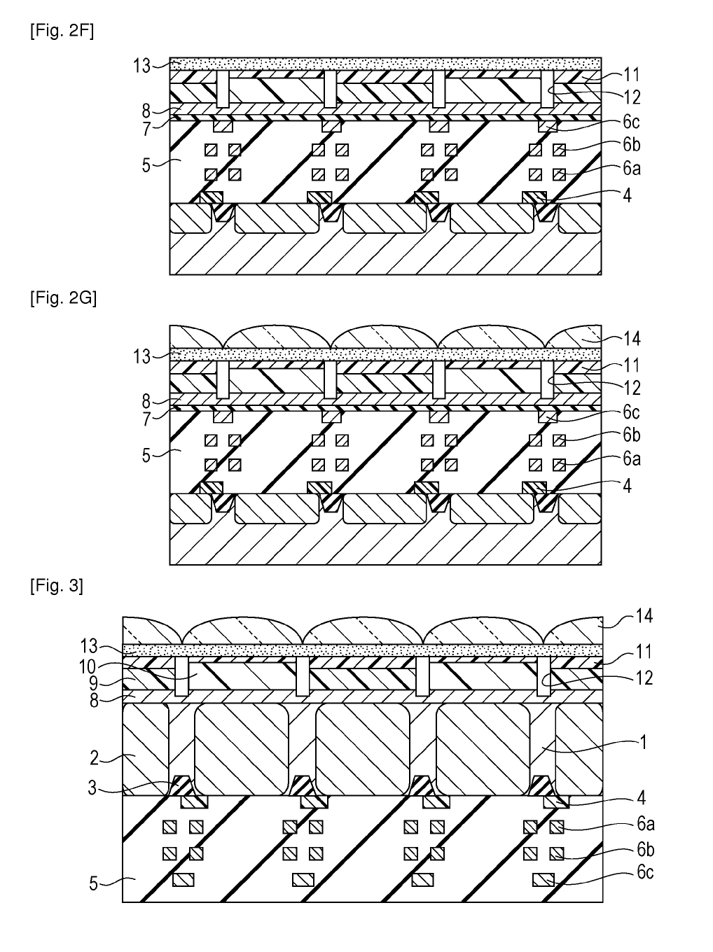

FIGS. 2A to 2G illustrate a production process flow of the solid-state image pickup device of this embodiment.

Referring to FIG. 2A, a structure up to the first planarizing layer 8 is initially formed using a known production method. The first planarizing layer 8 can function as an underlying layer of the color filter layer.

FIG. 2B illustrates a process in which the color filter layer is formed. A resin including a pigment for forming the first color filters 9 is applied over the entire area of the first planarizing layer 8 and patterned in an exposure process to remove unnecessary portions of the resin. Then, a resin including another pigment, for forming the second color filters 10, is applied over the entire area of the resultant structure, and is patterned in a process similar to that performed for forming the first color filters 9. The third color filters are formed according to need in a process similar to that performed for forming the first and second color filters 9 and 10. At this time, the different color filters may have different film thicknesses. In addition, in some cases, the second color filters 10 may be formed such that the second color filters 10 partly cover the first color filters 9 in boundary portions. This further increases the level difference in the boundary portions.

FIG. 2C illustrates a process of forming the second planarizing layer 11. The second planarizing layer 11 is formed on the above-described color filter layer so as to eliminate the level difference between the color filters. As a material of the second planarizing layer 11, for example, a resin may be used. Alternatively, the second planarizing layer 11 may be formed by forming an inorganic insulation film such as a silicon oxide film and then planarizing the surface of the resultant film.

FIG. 2D illustrates a photo resist process for forming the gaps 12. In this process, a photo resist is applied over the entire area of the surface, and then portions of the photo resist corresponding to the boundaries between neighboring pixels are removed by photolithography.

FIG. 2E illustrates an etching process for forming the gaps 12. The gaps 12 are formed by dry-etching using the above-described photoresist mask pattern. Here, an etching end point is determined by time, and etching is stopped at an intermediate position in the first planarizing layer 8. Etching may alternatively be stopped using an upper surface of the first planarizing layer 8 or using the protective layer 7. However, the gaps 12 penetrate through at least the color filter layer.

FIG. 2F illustrates a process in which the sealing layer 13 is formed. The sealing layer 13 is arranged at least on the gaps 12 so as to seal the gaps 12. The sealing layer 13 can be formed so as to cover the second planarizing layer 11 and the gaps 12. Resin, for example, can be used as a material of the sealing layer 13. The sealing layer 13 may also partly fill the gaps 12.

FIG. 2G illustrates a process in which the micro lenses 14 are formed. The micro lenses 14 are formed in such a manner that each micro lens 14 is positioned so as to cause light to enter an area partitioned by the gaps 12. The micro lenses 14 may be formed by patterning the resin and then baking the resin in a reflow process. The micro lenses 14 may alternatively be formed in a transfer etching process using a mask-shaped resist pattern.

By performing the above-described process, the solid-state image pickup device of this embodiment can be produced.

According to this embodiment, the level difference in the color filter layer is reduced with the second planarizing layer 11 before the gaps 12 are sealed with the sealing layer 13. Therefore, flatness can be maintained also at the boundaries between the color filters. This provides an optical advantage. In addition, when the micro lenses 14 are formed above the second planarizing layer 11 as in this embodiment, the level difference at the boundaries between the color filters is reduced in advance. This facilitates the formation of the micro lenses 14 in a desired shape.

### Second Embodiment

FIG. 3 illustrates a sectional view of the solid-state image pickup device of a second embodiment. Components having functions the same as those of the components described in the first embodiment are denoted by like reference numerals and detailed descriptions thereof are omitted. A difference between this embodiment and the first embodiment is that, in this embodiment, the incident direction of light is opposite to the direction in the first embodiment. In the first embodiment, light enters from a principal surface side (first principal surface side) where the wiring layer and the transistors are formed. In this embodiment, however, light enters from another principal surface side (second principal surface side) that is opposite to the surface side where the wiring layer and the transistors are formed. That is, the solid-state image pickup device of this embodiment is a so-called back-illuminated solid-state image pickup device.

Advantages equal to those achieved with the first embodiment can also be achieved with this embodiment.

### Third Embodiment

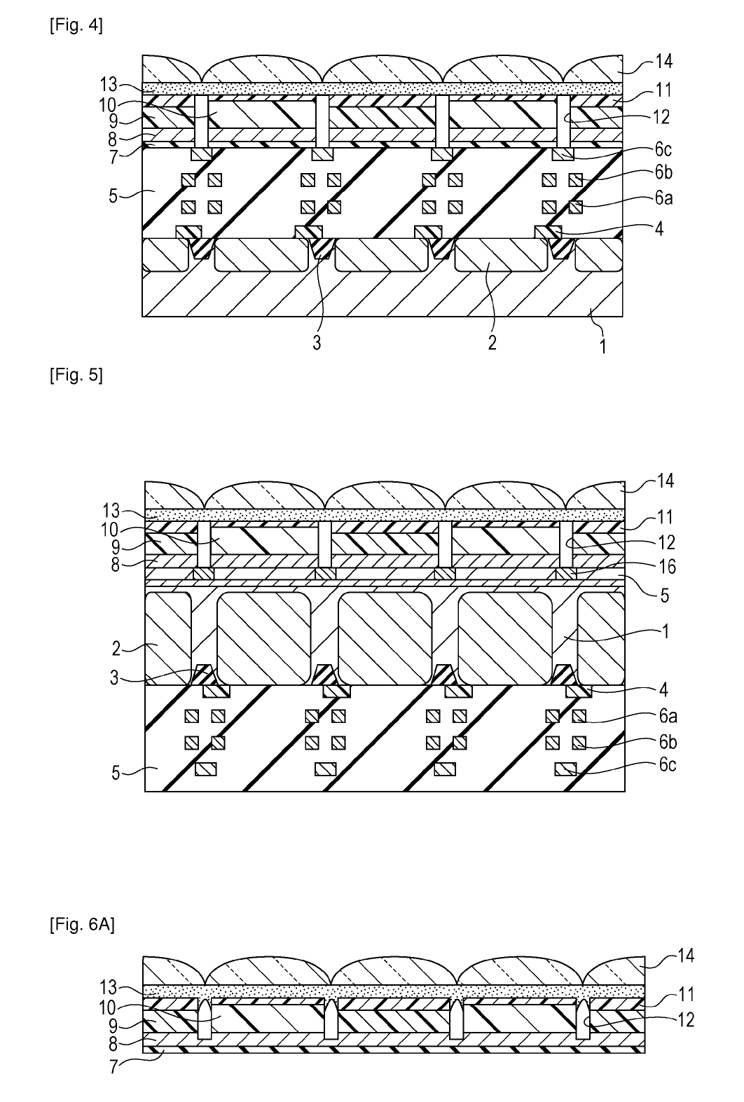

FIG. 4 illustrates a sectional view of the solid-state image pickup device of a third embodiment. Components having functions the same as those of the components described in the first embodiment are denoted by like reference numerals and detailed descriptions thereof are omitted. A difference between this embodiment and the first embodiment or the second embodiment is that, in this embodiment, the gaps 12 reach the top wiring layer 6c. The top wiring layer 6c is used as light-shielding portions or as wiring for supplying power. Such a structure can be formed, for example, by using the wiring layer 6c as an etching stop film in forming the gaps 12 in a production process. In addition to the advantages described in the first embodiment and the second embodiment, this structure enables the gaps 12 to divide the protective layer 7 into sections separated from each other. Therefore, light separation characteristics between neighboring pixels can be further improved.

### Fourth Embodiment

FIG. 5 illustrates a sectional view of the solid-state image pickup device of a fourth embodiment. Components having functions the same as those of the components described in the third embodiment are denoted by like reference numerals and detailed descriptions thereof are omitted. A difference between this embodiment and the third embodiment is that, in this embodiment, the solid-state image pickup device is the back-illuminated solid-state image pickup device.

Reference numeral 16 denotes light-shielding portions. The light-shielding portions 16 can be formed of metal or a black-coated resin. The light-shielding portions 16 are formed on the second principal surface side of the semiconductor substrate with an insulation film provided therebetween. The light-shielding portions 16 are disposed at the boundaries between the pixels. Areas surrounded by the light-shielding portions 16 correspond to the photoelectric conversion units. In the back-illuminated solid-state image pickup device, the wiring layer or the transistors are not disposed between the light-shielding portions 16 and the photoelectric conversion units. Therefore, the areas defined by the light-shielding portions 16 directly serve as apertures of individual photoelectric conversion units. In addition, the gaps 12 in this structure reach the light-shielding portions 16. If the gaps 12 are vertically projected onto the light-shielding portions 16, the areas of the gaps 12 are partly superposed with the areas of the light-shielding portions 16. The vertical projections of the gaps 12 on the light-shielding portions 16 can be completely included in the light-shielding portions 16.

Such a structure can be formed, for example, by using the light-shielding portions 16 as the etching stop film in forming the gaps 12 in the production process.

In addition to the advantages described in the above-described embodiments, this structure can improve both color separation characteristics between neighboring pixels and an aperture ratio because the vertical projections of the gaps 12 on the light-shielding portions 16 are superposed with the light-shielding portions 16.

### Fifth Embodiment

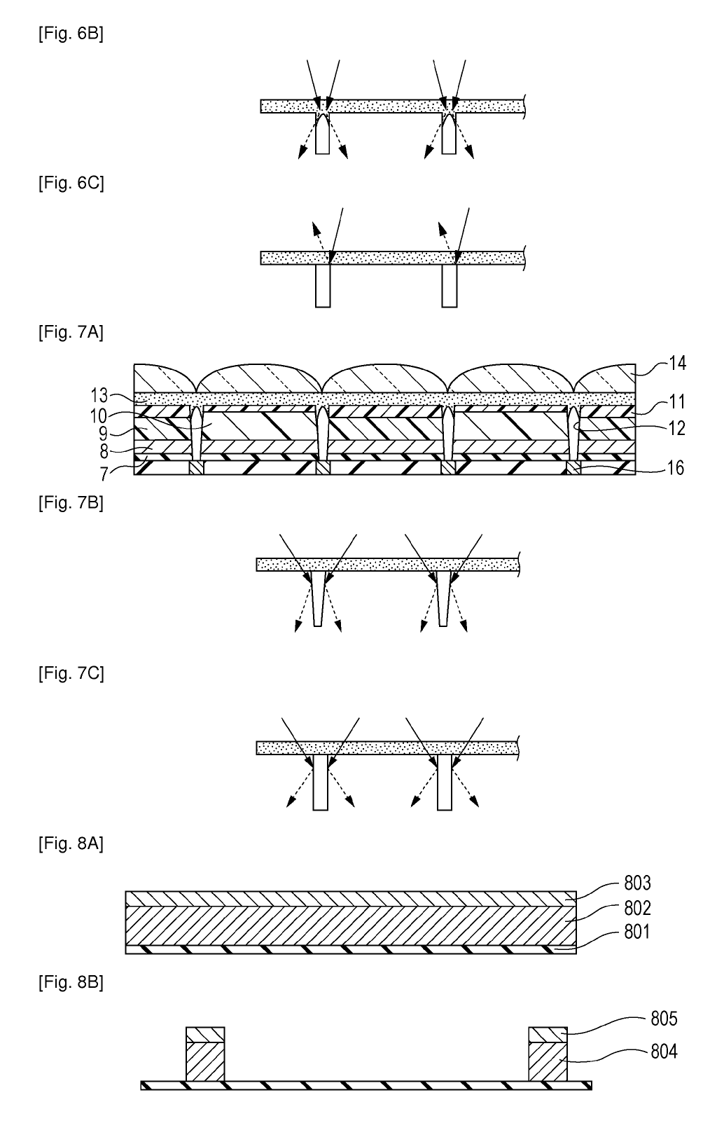

FIG. 6A illustrates a sectional view of the solid-state image pickup device of a sixth embodiment. Components having functions the same as those of the components of the above-described embodiments are denoted by like reference numerals and detailed descriptions thereof are omitted. A difference between this embodiment and the above-described embodiments is that, in this embodiment, a top portion of each gap 12 is formed so as to have an upwardly convex shape. The structure having the upwardly convex shape here refers to a structure that is convex so as to protrude in a direction away from the semiconductor substrate. In other words, this is a structure that is convex toward the incident light. Such a structure enables the solid-state image pickup device to efficiently divide the light having entered each gap 12 between the pixels on the left and right in the figure. This can improve photosensitivity. FIG. 6B illustrates the structure of this embodiment. FIG. 6C illustrates a structure of a comparative example. As FIG. 6B illustrates, the light having entered each gap 12 is reflected by a portion formed to have an upwardly convex shape in each gap 12, and is divided between the left and right pixels. In contrast, in the structure illustrated in FIG. 6C, part of the light is reflected by an interface between each gap 12 and the sealing layer 13. In such a structure, the light having entered each gap 12 cannot be utilized. Therefore, the light is not highly efficiently utilized and, in some cases, the reflected light may enter a neighboring pixel and cause noise.

The upwardly convex shape can be controlled by appropriately adjusting the size of the gaps 1 (width, depth, and aspect ratio) and the viscosity of the sealing layer 13.

In addition to the advantages described in the above-described embodiments, this embodiment also enables the light having entered each gap 12 to be efficiently utilized. Therefore, efficiency with which light is utilized can be improved.

### Sixth Embodiment

FIG. 7A illustrates a sectional view of the solid-state image pickup device of a sixth embodiment. Components having functions the same as those of the components of the above-described embodiments are denoted by like reference numerals and detailed descriptions thereof are omitted. A difference between this embodiment and the above-described embodiments is that, in this embodiment, each gap 12 is formed to have a tapered shape when seen from the interface between each gap 12 and sealing layer 13. In other words, side surfaces of each color filter are formed to have a reverse-tapered shape when seen from the interface with the sealing layer 13. The tapered shape can be formed by controlling conditions in the etching process and the shape of the photoresist mask.

FIG. 7B illustrates a structure in which each gap 12 is tapered. FIG. 7C illustrates a structure in which each gap 12 is not tapered as a comparative example. Compared to the structure illustrated in FIG. 7C, the structure in FIG. 7B enables incident light to be condensed into areas closer to central portions of the photoelectric conversion units. This capability becomes more important as the pixels become finer. The capability becomes especially effective when the pitch of the pixels is less than or equal to 2 micrometers.

In addition to the advantages described in the above-described embodiments, this embodiment enables the light reflected by the interfaces of the gaps 12 to be efficiently condensed into the central portions of the photoelectric conversion units. Therefore, photosensitivity can be further improved.

### Seventh Embodiment

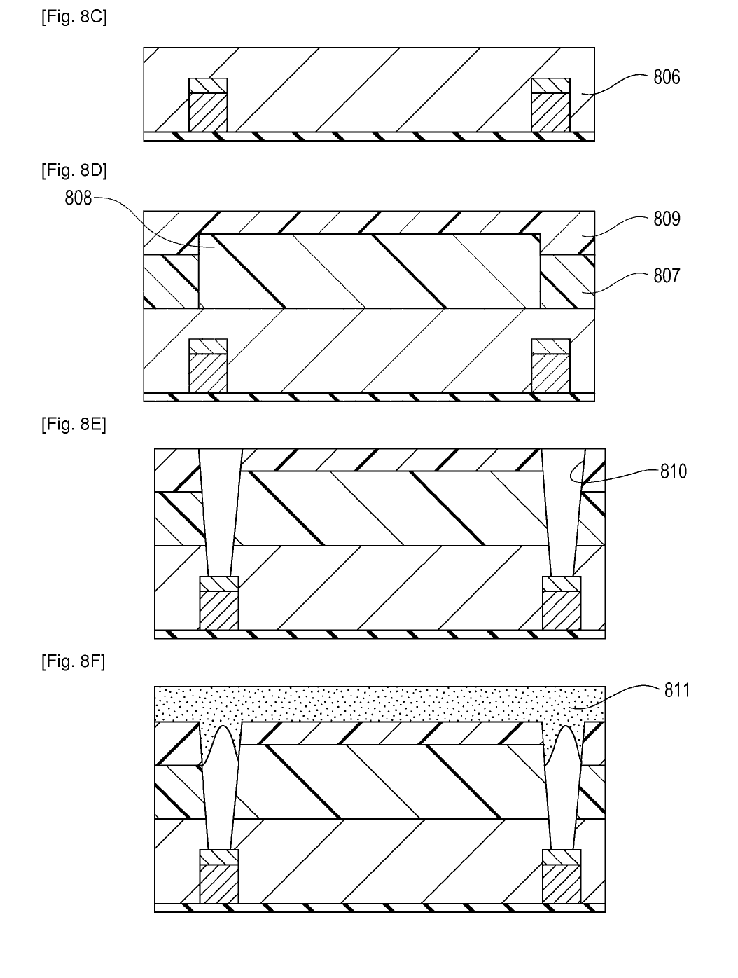

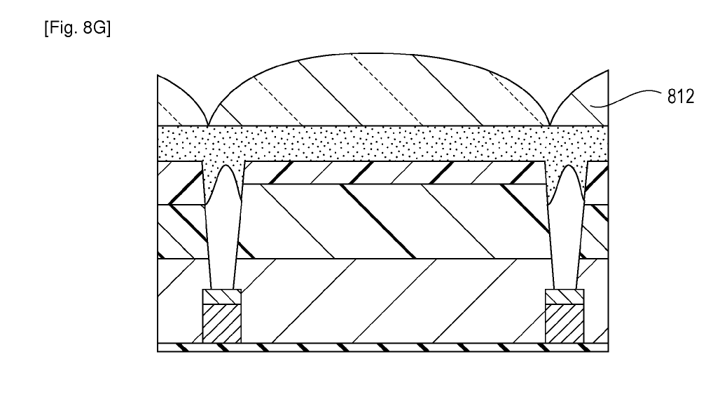

FIGS. 8A to 8G illustrate a production process flow of the solid-state image pickup device of a seventh embodiment. A difference between this embodiment and the above-described embodiments is that, in this embodiment, a protective layer of light-shielding portions is provided on the light-shielding portions. The protective layer of the light-shielding portions can be structured such that the protective layer of the light-shielding portions remains only on the light-shielding portions. In such a structure, the degree of photosensitivity is not reduced since a refractive index difference is not generated in the optical path of incident light. The production process flow will be sequentially described below. Although this embodiment is described with respect to the back-illuminated solid-state image pickup device, the description can also be applicable to a front-illuminated solid-state image pickup device.

In FIG. 8A, an insulation layer 801, a light-shielding portion material layer 802, and a protective layer material layer 803 are formed on the principal surface of a semi-conductor substrate.

In FIG. 8B, the light-shielding layer material layer 802 and the protective layer material layer 803 are patterned to form light-shielding portions 804 at the boundaries between the pixels and a protective layer 805 of the light-shielding portions 804 on the light-shielding portions 804.

In FIG. 8C, a first planarizing layer 806 is formed so as to cover the light-shielding portions 804 and the protective layer 805 of the light-shielding portions 804.

In FIG. 8D, a color filter layer including color filters 807 and color filters 808, which are differently colored from each other, are formed. Color filters having a number of different colors can be further provided. After the color filter layer has been formed, a second planarizing layer 809 is formed so as to reduce the level difference between color filters.

In FIG. 8E, gaps 810 are formed. After a resist mask, which is not shown, has been formed, the second planarizing layer 809 and the color filter layer are etched so that vertical projections of the gaps 810 on the semiconductor substrate are partly superposed with the protective layer 805 of the light-shielding portions 804. The entire vertical projections of the gaps 810 can be included in the protective layer 805 of the light-shielding portions 804.

Etching is stopped by the protective layer 805 of the light-shielding portions 804. Here, since the gaps 810 are disposed so that the vertical projections thereof are superposed with the protective layer 805 of the light-shielding portions 804, a reticle used in the formation of the protective layer 805 of the light-shielding portions 804 illustrated in FIG. 8B can be used to form a resist mask pattern for forming the gaps 810. By doing this, the number of reticles can be reduced. In addition, this can reduce a shift of the vertical projections of the gaps 810 from the protective layer 805 of the light-shielding portions 804.

In addition to the advantages described in the above-described embodiments, this embodiment has a structure in which surfaces of the light-shielding portions 804 are not exposed through the gaps 810. This can improve the reliability of the light-shielding portions 804.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-291023, filed Dec. 22, 2009, which is hereby incorporated by reference herein in its entirety.

2 Photoelectric conversion unit

8 First planarizing layer

9 Color filter

10 Color filter

11 Second planarizing layer

12 Gap

13 Sealing layer

1. A solid-state image pickup device comprising:
a plurality of photoelectric conversion units that are disposed in a semiconductor substrate;
a first planarizing layer that is disposed at a first principal surface side of the semiconductor substrate where light enters;
a color filter layer that is disposed on the first planarizing layer and includes color filters each of which is provided for a corresponding photoelectric conversion unit; and
a second planarizing layer that is disposed on the color filter layer and reduces a level difference between the color filters,
wherein a gap is disposed in a position corresponding to a boundary between the neighboring color filters in the color filter layer, the gap extending to the second planarizing layer, and a sealing layer for sealing the gap is disposed on the gap and the second planarizing layer.

2. The solid-state image pickup device according to claim 1, wherein a plurality of wiring layers are disposed at a second principal surface side of the semiconductor substrate, the second principal surface side being opposite to the first principal surface side of the semiconductor substrate.

3. The solid-state image pickup device according to claim 1, wherein a light-shielding portion is disposed between the semiconductor substrate and the color filter layer, and part of a vertical projection of the gap on the light-shielding portion is superposed with the light-shielding portion.

4. The solid-state image pickup device according to claim 3, wherein a protective layer of the light-shielding portion is disposed on the light-shielding portion.

5. The solid-state image pickup device according to claim 1, wherein the gap is formed to have an upwardly convex shape.

6. The solid-state image pickup device according to claim 1, wherein the gap is formed to have a tapered shape.

7. The solid-state image pickup device according to claim 1, wherein micro lenses for the corresponding photoelectric conversion units are provided on the second planarizing layer.

8. A method of producing a solid-state image pickup device, the method comprising:
forming a plurality of photoelectric conversion units in a semiconductor substrate;
forming a first planarizing layer at a first principal surface side of the semiconductor substrate where light enters;
forming a color filter layer on the first planarizing layer, the color filter layer including color filters each of which is provided for a corresponding photoelectric conversion unit;
forming a second planarizing layer on the color filter layer, the second planarizing layer reducing a level difference between the color filters;
forming a gap in a position corresponding to a boundary between the neighboring color filters in the color filter layer, the gap penetrating through the second planarizing layer and the color filter layer; and
forming a sealing layer on the gap and the second planarizing layer.

9. The method of producing the solid-state image pickup device according to claim 8, the method further comprising:
forming a light-shielding portion on a first principal surface of the semiconductor substrate where light enters with a layer insulation film provided between the semiconductor substrate and the light-shielding portion,
wherein the light-shielding portion functions as an etching stop film when the gap is formed by etching.

10. The method of producing the solid-state image pickup device according to claim 8, the method further comprising:
forming a light-shielding portion on a first principal surface of the semiconductor substrate where light enters with a layer insulation film provided between the semiconductor substrate and the light-shielding portion; and
forming a protective layer of the light-shielding portion on the light-shielding portion,
wherein the protective layer of the light-shielding portion functions as an etching stop film when the gap is formed by etching.
